(19) United States
(12) Patent Application Publication
(10) Pub. No.: US 2016/0322404 A1
(43) Pub. Date: Nov. 3, 2016

(54) METHODS FOR PRODUCING TFT ARRAY SUBSTRATE AND DISPLAY APPARATUS

(71) Applicants: BOE TECHNOLOGY GROUP CO., LTD, Beijing (CN); BEIJING BOE OPTOELECTRONICS TECHNOLOGY CO., LTD., Beijing (CN)

(72) Inventors: Xiaohui Jiang, Beijing (CN); Jiaxiang Zhang, Beijing (CN)

(21) Appl. No.: 15/083,017

(22) Filed: Mar. 28, 2016

(30) Foreign Application Priority Data
Apr. 30, 2015 (CN) 201510219228.4

(51) Int. Cl. H01L 27/12; H01L 29/786; H01L 29/66

(52) U.S. Cl. CPC H01L 27/1288; H01L 29/66765; H01L 29/78669; H01L 29/78696; H01L 29/78618; H01L 27/1222

(57) ABSTRACT

Embodiments of the present disclosure provide a method for producing a TFT array substrate and a method for producing a display apparatus. The method for producing the TFT array substrate includes forming a semiconductor layer onto a substrate, and forming a shading pattern onto the semiconductor layer at a position at least corresponding to a channel region of the semiconductor layer, wherein the shading pattern contacts with the semiconductor layer; forming a transparent electrode of ITO material onto the substrate formed with the shading pattern, and removing the shading pattern after forming the transparent electrode.

### CROSS-REFERENCE TO RELATED APPLICATION

This application claims the benefit of Chinese Patent Application No. 201510219228.4 entitled “Methods for Producing TFT Array Substrate and Display Apparatus”, filed on Apr. 30, 2015 in the State Intellectual Property Office of China, the whole disclosure of which is incorporated herein by reference.

### BACKGROUND OF THE INVENTION

1. Field of the Invention

The present application relates to a technical field of display, more particular to a method for producing TFT array substrate and a method for producing a display apparatus.

2. Description of the Related Art

ITO (Indium Tin Oxide) is used to manufacture transparent electrodes, due to advantages of such as relatively high electrical conductivity and light transmissivity, good adhesion and stability, and being etched by acid.

However, because there are a lot of factors influencing deposition of ITO, for example, temperature change of the substrate, change of depositing rate of ITO, adjustment of amount of water vapor upon depositing the ITO, these may result in change of crystal morphology of ITO, thereby generating etching residuals after the etching process.

Manufacturing an array substrate of a liquid crystal display apparatus is taken as one example. As shown in FIG. 1, during the process of forming pixel electrodes 50, it will produce ITO residuals 501, especially, when the ITO residuals 501 are located within a channel region of a semiconductor layer 40 and contact with the channel region of a semiconductor layer 40, this will cause badness such as abnormity of product property, too large leakage of current, and high temperature stain generated during a reliability test.

Currently, it is common to replace ITO by IZO (Indium Zinc Oxide), but it is easy for surfaces of IZO to oxidize and a target material thereof is very expensive.

### SUMMARY OF THE INVENTION

Embodiments of the present application provide a method for producing a TFT array substrate and a method for producing a display apparatus, which can avoid generating the ITO residuals at the channel region.

For this end, the present embodiments employ the following technical solutions:

In one aspect, a method for producing a TFT array substrate comprises:

forming a semiconductor layer onto a substrate, and forming a shading pattern onto the semiconductor layer at a position at least corresponding to a channel region of the semiconductor layer, wherein the shading pattern contacts with the semiconductor layer; and

forming a transparent electrode of ITO material onto the substrate formed with the shading pattern, and removing the shading pattern after forming the transparent electrode.

In one example, the shading pattern is removed by means of a material not reacting with the ITO material of the transparent electrode.

In one example, the shading pattern and the semiconductor layer are formed by one same patterning process.

In one example, the shading pattern is made of photoresist material.

In one example, the step of forming the shading pattern and the semiconductor layer by one same patterning process further comprises:

forming a semiconductor film onto the substrate, and forming a photoresist film onto the semiconductor film;

exposing the photoresist film formed over the substrate by a gray tone mask or a half tone mask to a light, and developing it to form a part of fully reserved photoresist, a part of semi-reserved photoresist and a part of fully removed photoresist;

removing the semiconductor film located at a position corresponding to the part of the fully removed photoresist by an etching process so as to form the semiconductor layer;

removing the photoresist of the part of the semi-reserved photoresist by an ashing process, and forming the shading pattern by the part of the fully reserved photoresist.

In one example, the part of fully reserved photoresist corresponds to a region of the semiconductor layer onto which the shading pattern is to be formed, the part of semi-reserved photoresist corresponds to other regions in the semiconductor layer except the region corresponding to the shading pattern, and the part of fully removed photoresist corresponds to other regions of the substrate except the semiconductor layer.

In one example, the semiconductor layer comprises an amorphous silicon layer or an n+ amorphous silicon layer.

In one example, after forming the transparent electrode and removing the shading pattern, the method further comprises:
etching the channel region of the semiconductor layer so as to expose the amorphous silicon layer.

In one example, the method further comprises forming source and drain electrodes, and etching the channel region of the semiconductor layer and forming the source and drain electrodes by one same patterning process.

In one example, the step of etching the channel region of the semiconductor layer and forming the source and drain electrodes by one same patterning process comprises:

after forming the transparent electrode and removing the shading pattern, forming a metal film and forming a photoresist film on the metal film;

exposing the photoresist film formed over the substrate by a mask to a light, and developing it to form a part of fully reserved photoresist and a part of fully removed photoresist;

forming the source and drain electrodes by removing the metal film located at a position corresponding to the part of fully removed photoresist by an etching process, and etching the channel region of the semiconductor layer so as to expose the amorphous silicon layer; and

removing the photoresist film of the part of fully reserved photoresist.

In one example, the part of fully reserved photoresist corresponds to a region where a conductive layer comprising the source and drain electrodes is to be formed, and the part of fully removed photoresist corresponds to other regions of the substrate except the conductive layer.

In one example, after forming the shading pattern but before forming the transparent electrode, the method further comprises forming source and drain electrodes.

In one example, the transparent electrode is a pixel electrode.

In one example, the method further comprises forming a passivation layer and a common electrode.

In another aspect, a method for producing a display apparatus comprises the method for producing the array substrate as described above.

In one example, the method further comprises forming a color filter substrate and assembling the array substrate and the color filter substrate.

Embodiments of the present application provide a method for producing a TFT array substrate and a method for producing a display apparatus. Before forming the transparent electrode of the ITO material, a shading pattern is formed to at least cover the channel region of the semiconductor layer. In this way, after forming the transparent electrode, the generated ITO residuals are located onto the shading pattern. After removing the shading pattern, the ITO residuals can be removed at the same time, thereby avoiding the ITO residuals being onto the channel region.

### BRIEF DESCRIPTION OF THE DRAWINGS

In order to more clearly explain technical solutions in the present embodiments and in the prior art, the drawings used therein are briefly set out below. It is obvious that the accompanying drawings are only directed to some embodiments of the present application. The ordinary skilled person in the art can also obtain other drawings based on these figures without any creative labor.

FIG. 1 is a schematic view showing a structure of generated ITO residuals at a channel region of a semiconductor layer provided by the prior art upon forming pixel electrodes;

FIG. 2 is a schematic view of flowchart of a method for manufacturing TFT array substrate in accordance with an embodiment of the present application;

FIG. 3 is a schematic view showing a structure of a semiconductor layer and a shading pattern formed according to the embodiment of the present application;

FIG. 4 is a schematic view showing a structure of a transparent electrode and ITO residuals formed on basis of FIG. 3;

FIG. 5 is a schematic view showing a structure after removing the shading pattern on basis of FIG. 4;

FIGS. 6a-6d are schematic views for a process of forming the semiconductor layer and the shading pattern in accordance with an embodiment of the present application;

FIGS. 7a-7c are schematic views for a process of forming source and drain electrodes while etching a channel region of the semiconductor layer in accordance with an embodiment of the present application;

FIG. 8 is a schematic view showing a structure of forming the source and drain electrodes just after forming the shading pattern in accordance with another embodiment of the present application; and

FIG. 9 is a schematic view showing a structure of an array substrate in accordance with an embodiment of the present application.

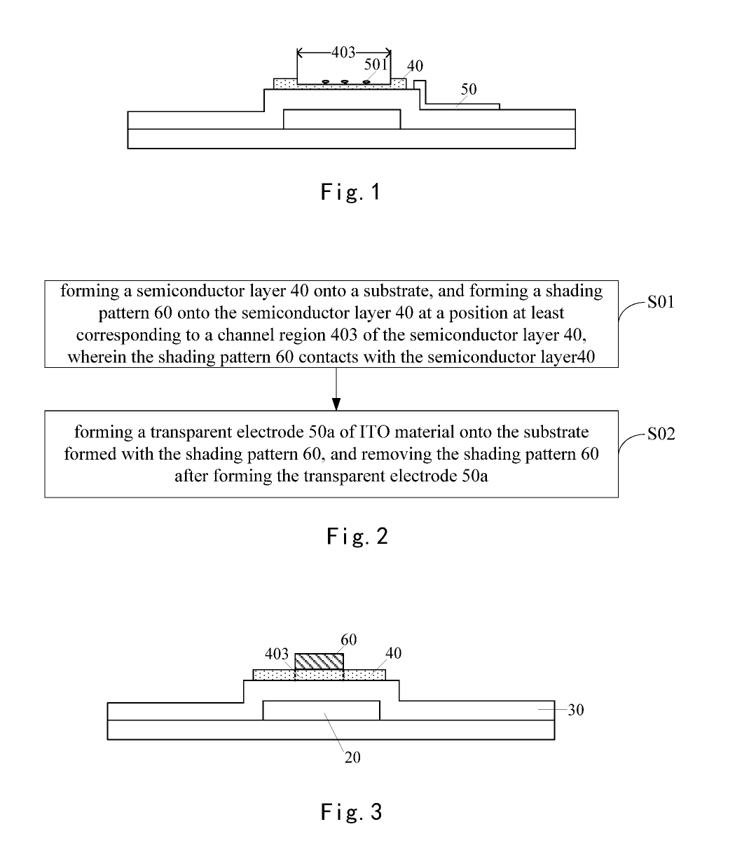

### EXPLANATION OF REFERENCE NUMBERS

20: gate electrode; 30: gate insulation layer; 40a: semiconductor film; 40 semiconductor layer; 401 amorphous silicon layer; 402: n+ amorphous silicon layer; 403:

channel region; 50a: transparent electrode; 50: pixel electrode; 501: ITO residuals; 60: semiconductor layer; 70: photoresist film; 701: part of fully reserved photoresist; 702: part of semi-reserved photoresist; 703: part of fully removed photoresist; 80: gray tone mask or half tone mask; 801: fully opaque portion; 802: semi-transparent portion; 803: fully transparent portion; 90a: metal film; 901: source electrode; 902: drain electrode; 100: passiviation layer; 110: common electrode

### DETAINED DESCRIPTION OF PREFERRED EMBODIMENTS OF THE INVENTION

Below, technical solutions of embodiments of the present application are clearly and fully described with reference to the drawings directed to the present embodiments. Obviously, the described embodiments herein are only some, not all embodiments of the present application. On basis of the embodiments of the present application, all other embodiments which can be obtained by the ordinary skilled person in the art without any inventive work, shall fall within the scope of the present application.

An embodiment of the present application provides a method for producing a TFT array substrate, as shown in FIG. 2. The method includes the steps S01 and S02 as follows.

As shown in FIG. 3, the step S01 is to form a semiconductor layer 40 on a substrate and to form a shading pattern 60 onto the semiconductor layer 40 which at least corresponds to a channel region 403 of the semiconductor layer 40. The shading pattern 60 contacts the semiconductor layer 40, preferably, directly contacts the semiconductor layer 40.

In one example, a material for the semiconductor layer 40 can be amorphous silicon, metal oxide, or other suitable semiconductor materials. It should be considered to etch the channel region 403 of the semiconductor layer 40, when the semiconductor layer 40 is made of amorphous silicon material, i.e., the semiconductor layer 40 includes amorphous silicon layer and n+ amorphous silicon layer. As for this, the shading pattern 60 can be formed onto the channel region 403 of the semiconductor layer 40 before etching as shown in FIG. 3, or after the etching. Of course, there is no need to etch the channel region in the case that the semiconductor layer 40 is made of other materials except the amorphous silicon. Just as shown in FIG. 3, the shading pattern 60 is formed on the channel region 403 of the semiconductor layer 40.

In addition, the shading pattern 60 at least corresponds to the channel region 403 of the semiconductor layer 40. The shading pattern 60 may only correspond to the channel region 403 of the semiconductor layer 40, or also correspond to other regions of the semiconductor layer 40 besides the channel region 403, as long as it does not influence the subsequently formed transparent electrode 50a. The present embodiment does not make any limitation to the material of the shading pattern 60, as long as the material of the shading pattern 60 is not remained onto the channel region 403 after removing the shading pattern 60.

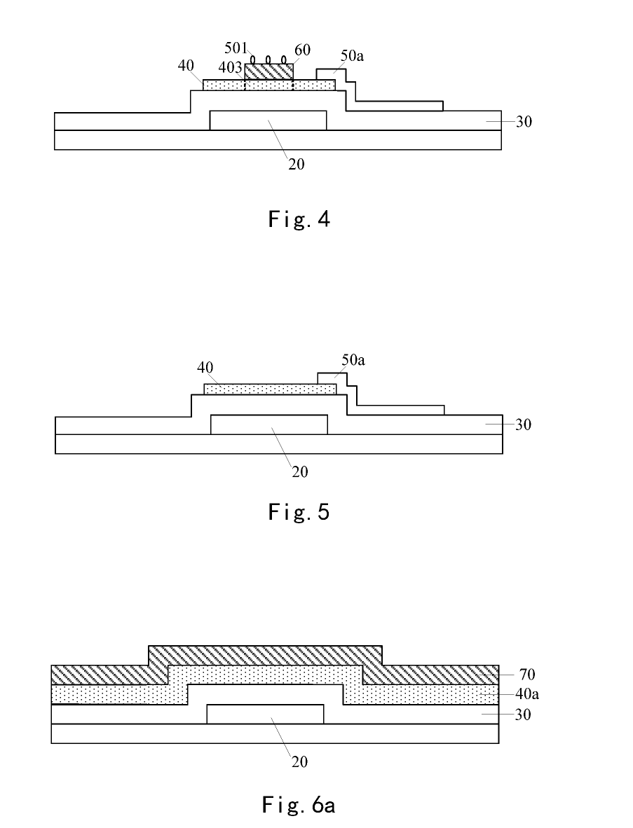

As shown in FIGS. 4 and 5, the step S02 is to form the transparent electrode 50a of ITO material onto the substrate formed with the shading pattern 60, and to remove the shading pattern 60 after forming the transparent electrode 50a.

Herein, it is preferable to remove the shading pattern with a material which makes no reaction with the ITO material.

Illustratively, the material of the shading pattern 60 may be photoresist. On basis of this, the shading pattern 60 can be removed by a stripping liquid. Since the ITO material can only be etched by strong acid such as sulphuric acid, nitric acid, acetic acid, the stripping liquid makes no influence on the transparent electrode 50a of the ITO material.

The transparent electrode 50a can be for example a source electrode or a drain electrode, and in this case the TFT may be transparent. The transparent electrode 50a may also be a pixel electrode, or a common electrode.

Please be noted that the present embodiment and FIGS. 3-5 are described taking firstly forming the gate electrode 20 and the gate insulation layer 30 and then forming the semiconductor layer 40 as an example. However, the present embodiment is not limited to this, and can be set according to the actual requirement.

In addition, the present application does not make any limitation to the process of forming the shading pattern 60 and the semiconductor layer 40.

A further embodiment of the present application provides a method for producing the TFT array substrate: forming a shading pattern 60 to at least cover a channel region 403 of the semiconductor layer 40 before forming the transparent electrode 50a of the ITO material, so that after forming the transparent electrode 50a the generated ITO residuals 501 are located onto the shading pattern 60. In this way, the shading pattern 60 and the ITO residuals 501 located thereon are removed together, so as to avoid generation of the ITO residuals 501 onto the channel region 403.

Preferably, the shading pattern 60 and the semiconductor layer 40 can be formed by one patterning process.

In the present embodiment, the one patterning process is directed to once mask process, and meant to finish some pattern layers by applying the mask once. It at least includes coating of photoresist, exposure, development, etching or the like after application of the mask.

In this way, during forming the TFT array substrate, it may avoid increase of the number of patterning process caused by the production of the shading pattern 60.

Further preferably, the material of the shading pattern 60 is photoresist. On basis of this, the shading pattern 60 and the semiconductor layer 40 may be formed by one patterning process. Specifically, the step of forming the shading pattern 60 and the semiconductor layer 40 by one patterning process may include steps of S101-S104.

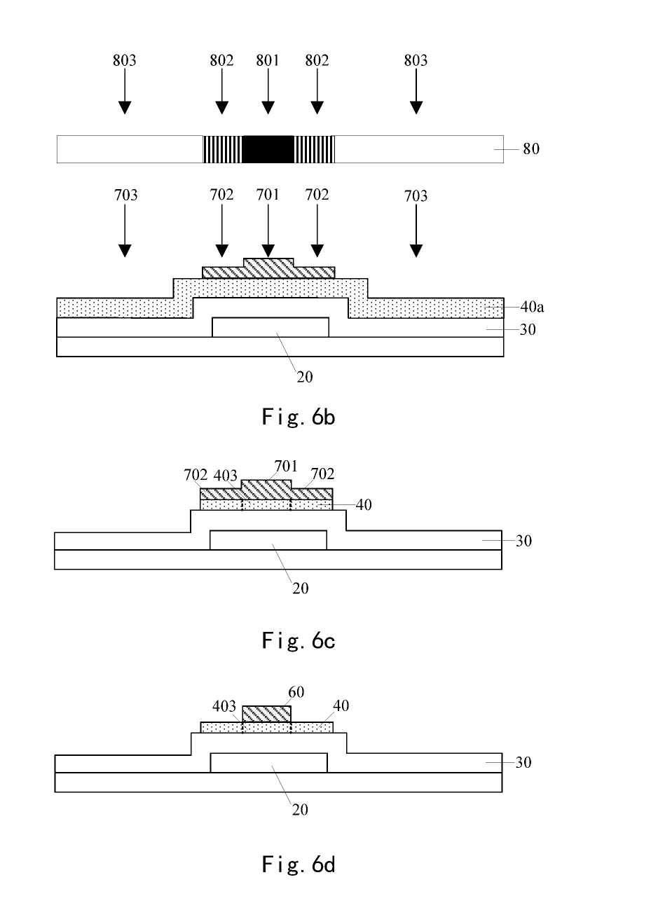

As shown in FIG. 6a, the step S101 is to form a semiconductor film 40a on the substrate and to form a photoresist film 70 onto the semiconductor film 40a. The substrate may be that shown in FIG. 6a formed with the gate electrode 20 and the gate insulation layer 30, or a base substrate without any pattern layer for forming the TFT, for example, one formed with only flat layer.

The present embodiment does not make any limitation to the material of the semiconductor film 40a, which can be amorphous silicon, metal oxide, or other suitable material. The present application does not make any definition therein.

When the semiconductor film 40a is made of amorphous silicon material, it is preferable to be a structure of two layers, i.e., the semiconductor film 40a includes a layer of amorphous silicon film and a layer of n+ amorphous silicon film (a film of ohmic contact layer).

The step S102 is as shown in FIG. 6b to expose the substrate formed with the photoresist film 70 by means of a gray tone mask 80 or a half tone mask to a light, and develop it to form a part of fully reserved photoresist 701, a part of semi-reserved photoresist 702 and a part of fully removed photoresist 703, wherein the part of fully reserved photoresist 701 corresponds to a region of the semiconductor layer 40 to form the shading pattern 60, the part of semi- reserved photoresist 702 corresponds to other regions of the semiconductor layer 40 except the shading pattern 60; and the part of fully removed photoresist 703 corresponds to other regions except the semiconductor layer 40.

With reference to FIG. 6b, the half tone mask 80 includes a fully opaque portion 801, a semi-transparent portion 802 and a fully transparent portion 803. The half tone mask 80 is one used to form an opaque light shading metal layer formed at some regions of the transparent substrate material, to form a semi transparent light shading metal layer at another some regions; and not to form any light shading metal layers at the remaining regions. Specifically, the semi transparent light shading metal layer has a thickness smaller than that of the fully opaque light shading metal layer. In addition, the light transmissivity of the semi transparent light shading metal layer to the ultra violet light can be changed by adjusting the thickness of the semi transparent light shading metal layer.

On basis of this, the working principle of the half tone mask 80 is explained as follows: the thickness of the light shading metal layer at different regions of the half tone mask 80 can be controlled so that the intensity of the light transmission at different regions during exposing it to a light becomes varied. In this way, the photoresist film 70 is exposed to a light and developed selectively to form the part of fully reserved photoresist 701, the part of semi-reserved photoresist 702 and part of fully removed photoresist 703 respectively corresponding to the fully opaque portion 801, the semi-transparent portion 802 and the fully transparent portion 803 of the half tone mask 80.

The principle of the gray tone mask is similar to that of the half tone mask 70, and is not repeatedly discussed again.

The photoresist in all of the above embodiments of the present application is meant to a positive photoresist. Of course, it can also be a negative photoresist. In this case, after the exposure, the part of fully reserved photoresist 701 corresponds to the fully transparent portion 803 of the half tone mask 80, and the part of fully removed photoresist 703 corresponds to the fully opaque portion 801 of the half tone mask 80. The specific principle is the same as described above and is not repeatedly discussed again.

The step S103 as shown in FIG. 6c is to form the semiconductor layer 40 by removing the semiconductor film 40a of the part of fully removed photoresist 703 through the etching process.

The step S104 as shown in FIG. 6d is to remove the photoresist of the part of semi-reserved photoresist 702 by ashing, and after this the part of fully reserved photoresist 701 forms the shading pattern 60.

Based on the above steps of S101-S104, when the semiconductor layer 40 includes the amorphous silicon layer 401 and the n+ amorphous silicon layer 402, it is possible to firstly form the transparent electrode 50a on the semiconductor layer 40, and after removing the shading pattern 60, to etch the channel region 403 of the semiconductor layer 40 so as to expose the amorphous silicon layer 401.

Herein, the person skilled in the art well knows that upon etching the channel region 403 of the semiconductor layer 40 including the amorphous silicon layer 401 and the n+ amorphous silicon layer 402, it is not limited to only etch away the n+ amorphous silicon layer 402 at the channel region 403, and also would etch away a part of the amorphous silicon layer 401 at the channel region 403. This will be performed by the conventional operating method and is not repeatedly described again.

Furthermore, the method also includes forming a source electrode 901 and a drain electrode 902. On basis of this, it is preferable that etching the channel region 403 of the semiconductor layer 40 and forming the source electrode 901 and the drain electrode 902 are finished by one patterning process.

Specifically, the process of etching the channel region 403 in the semiconductor layer 40 and forming the source and drain electrodes 901 and 902 by one patterning process can include the following steps of S201-S204.

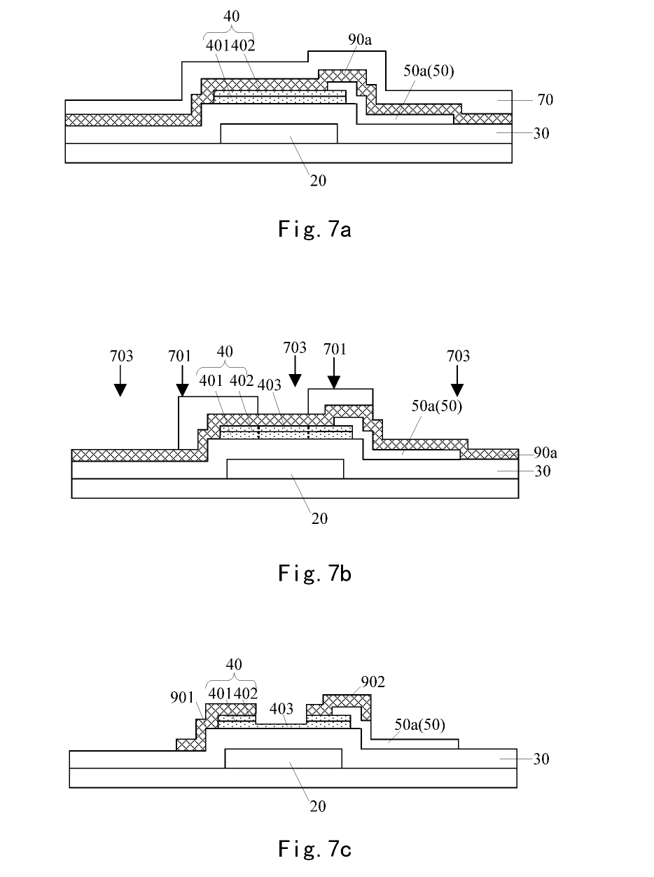

The step S201 as shown in FIG. 7a is to form a metal film 90a after forming the transparent electrode 50a and removing the shading pattern 60 and to form a photoresist film 70 on the metal film 90a.

The step S202 as shown in FIG. 7b is to expose the substrate formed with the photoresist film 70 by a mask for example an ordinary or common mask to a light, and develop it to form the part of fully reserved photoresist 701 and the part of fully removed photoresist 703; wherein the part of fully reserved photoresist 701 corresponds to the region of conductive layer to be formed and including the source and drain electrodes, and the part of fully removed photoresist 703 corresponds to other regions except the conductive layer to be formed.

Herein, the conductive layer also includes data lines.

The step S203 as shown in FIG. 7c is to form the source electrode 901 and the drain electrode 902 by removing the metal film 90a of the part of fully removed photoresist by the etching process, and to etch the channel region 403 of the semiconductor layer 40 so as to expose the amorphous silicon layer 401.

The step S204 as shown in FIG. 7c is to remove the photoresist film of the part of the fully reserved photoresist 701.

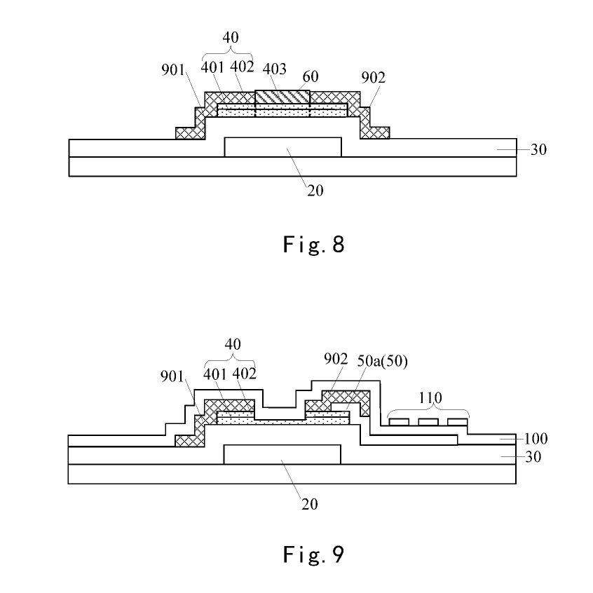

Of course, the source and drain electrodes 901 and 902 can be formed before the transparent electrode 50a. That is, as shown in FIG. 8, the source and drain electrodes 901 and 902 are formed after forming the shading pattern 60 and before forming the transparent electrode 50a. In this case, the shading pattern 60 only corresponds to the channel region 403 of the semiconductor layer 40.

On basis of this, the channel region 403 of the semiconductor layer 40 can be etched to expose the amorphous silicon layer 401, after forming the transparent electrode 50a and removing the shading pattern 60.

Based on the above description, taking into consideration that the source and drain electrodes made of the ITO material will cause relatively large electrical resistance, it is preferable to use the transparent electrode 50a as the pixel electrode 50.

Further, the array substrate provided by the present application is suitable for the production of ADS (Advanced Super Dimensional Switching) type of liquid crystal display apparatus. The key technical characteristic of ADS technique is described as: forming a multiple dimensional electric field by an electric field generated at edges of slit electrodes within the same plane and an electric field generated between the layer of slit electrodes and the layer of the plate-shaped electrodes, so that all the oriented liquid crystal molecules between the slit electrodes within the liquid crystal cell, and those directly above the electrodes can rotate, thereby improving the working efficiency of the liquid crystal and increasing the efficiency of light transmission. The ADS technology can improve picture quality of the TFT-LCD (thin film transistor liquid crystal display) product, and have the advantages such as high resolution, high transmissivity, low power consumption, a wide view angle, high aperture ratio, low chromatic aberration, without push mura or the like.

Therefore, preferably, the method for producing the array substrate also includes: forming a passivation layer 100 and a common electrode 110 as shown in FIG. 9.

The material for the common electrode 110 may be ITO. Here, even if there are ITO residuals during formation of the common electrode 110, it would not produce any influence to the performance of the array substrate.

Below, one specific embodiment is provided to describe the method for producing the array substrate as shown in FIG. 7c in detail. The method includes the following steps.

Step S301 is to manufacture a metal film on the substrate and form a gate electrode 20 by one patterning process. Specifically, the metal film can be manufactured onto the glass substrate by a method of magnetron sputtering. The metal material may generally be molybdenum, aluminum, alloy of aluminum and nickel, alloy of molybdenum and tungsten, chromium or cooper, or may be a combined structure of the material films as described above. And then, the gate electrode 20 and the gate line (not shown in the figure) or the like are formed onto a certain region of the substrate with the ordinary mask through the patterning processes such as exposure, development, etching, peeling off or the like.

Step S302 is to manufacture an insulation layer after the Step S301. Specifically, films of the insulation layer can be successively deposited onto the substrate by a chemical vapor deposition method. The material for the insulation layer film is normally silicon nitride, or silicon oxide or silicon oxynitride and the like.

Step S303 is to subsequently form a semiconductor film 40a after the step S302 and to form a photoresist film 70 onto the semiconductor film 40a, wherein the semiconductor film 40a includes a film of amorphous silicon and a film of n+ amorphous silicon.

Step S304 is to expose the substrate formed with the photoresist film 70 by the gray tone mask 80 to a light, after the step S303, and develop it to form the part of fully reserved photoresist 701, the part of semi-reserved photoresist 702 and the part of fully removed photoresist 703, wherein the part of fully reserved photoresist 701 corresponds to a region forming the shading pattern 60, the part of semi-reserved photoresist 702 corresponds to other regions of the semiconductor layer 40 except that corresponding to the shading pattern 60; and the part of fully removed photoresist 703 corresponds to other regions except the semiconductor layer 40.

The step S305 is to form the semiconductor layer 40 by removing the semiconductor film 40a of the part of fully removed photoresist 703 through the etching process after the step S304, and the silicon layer 40 includes a layer of amorphous silicon 401 and a layer of n+ amorphous silicon 402.

The step S306 is to remove the photoresist of the part of semi-reserved photoresist 702 by ashing process, after the step S305, and the part of fully reserved photoresist 701 forms the shading pattern 60.

The step S307 is to form a pixel electrode 50 of the ITO material by one patterning process and to remove the shading pattern 60 after the step S306.

The step 308 is to form a metal film 90a and to form a photoresist film 70 onto the metal film 90a after the step S307. Specifically, the metal film 90a can be manufactured onto the glass substrate by a method of magnetron sputtering. The metal material may generally be molybdenum, aluminum, alloy of aluminum and nickel, alloy of molybdenum and tungsten, chromium or cooper, or may be a combined structure of the material films as described above.

The step S309 is to expose the substrate formed with the photoresist film 70 by a mask for example an ordinary or conventional mask to a light, and to form the part of fully reserved photoresist 701 and the part of fully removed photoresist 703 after developing, after the step S308; wherein the part of fully reserved photoresist 701 corresponds to the region of a conductive layer to be formed and including the source and drain electrodes and data lines, and the part of fully removed photoresist 703 corresponds to other regions except the conductive layer to be formed.

The step S310 is after the step S309, to form the source electrode 901 and the drain electrode 902 as well as the data lines (not shown in the figure) by removing the metal film 90a of the part of fully removed photoresist by the etching process, and to etch the channel region 403 of the semiconductor layer 40 so as to expose the amorphous silicon layer 401.

The step S311 is to remove the photoresist film of the part of the fully reserved photoresist 701, after the step S310.

A further embodiment of the present application also provides a method for producing a display apparatus, including the method for producing the array substrate as described above. Further, it also includes the method for producing a color filter substrate. On basis of this, the method for producing the display apparatus further includes assembling the array substrate and the color filter substrate. The color filter substrate at least includes a red layer, a green layer, a blue layer and a black matrix. Of course, in the condition that the array substrate does not include the common electrode, the color filter substrate further includes the common electrode.

The above display apparatus can be any product or component having display function such as a liquid crystal display device, a liquid crystal television, a digital photo camera, a mobile phone, and a flat panel computer.

As described above, these embodiments are only the specific examples of the present application, but the scope of the present application is not limited to this. Any skilled person in the art can easily conceive changes or replacement within the disclosure of the present application, which shall be covered by the scope of the present application. Therefore, the scope of the present application should be defined by the appended claims.

1. A method for producing a thin film transistor (TFT) array substrate, comprising:
forming a semiconductor layer onto a substrate, and forming a shading pattern onto the semiconductor layer at a position at least corresponding to a channel region of the semiconductor layer, wherein the shading pattern contacts with the semiconductor layer; and
forming a transparent electrode of indium tin oxide (ITO) material onto the substrate formed with the shading pattern, and removing the shading pattern after forming the transparent electrode.

2. The method as claimed in claim 1, wherein the shading pattern is removed by means of a material not reacting with the ITO material of the transparent electrode.

3. The method as claimed in claim 1, wherein the shading pattern and the semiconductor layer are formed by a single patterning process.

4. The method as claimed in claim 3, wherein the shading pattern is made of photoresist material.

5. The method as claimed in claim 4, wherein the step of forming the shading pattern and the semiconductor layer by the single patterning process further comprises:
forming a semiconductor film onto the substrate, and forming a photoresist film onto the semiconductor film;
exposing the photoresist film formed over the substrate by a gray tone mask or a half tone mask to a light, and developing it to form a part of fully reserved photoresist, a part of semi-reserved photoresist and a part of fully removed photoresist;
removing the semiconductor film located at a position corresponding to the part of the fully removed photoresist by an etching process so as to form the semiconductor layer; and
removing the photoresist of the part of the semi-reserved photoresist by an ashing process, and forming the shading pattern by the part of the fully reserved photoresist.

6. The method as claimed in claim 5, wherein the part of fully reserved photoresist corresponds to a region of the semiconductor layer onto which the shading pattern is to be formed, the part of semi-reserved photoresist corresponds to other regions in the semiconductor layer except the region corresponding to the shading pattern, and the part of fully removed photoresist corresponds to other regions of the substrate except the semiconductor layer.

7. The method as claimed in claim 1, wherein the semiconductor layer comprises an amorphous silicon layer or an n+ amorphous silicon layer.

8. The method as claimed in claim 7, wherein after forming the transparent electrode and removing the shading pattern, the method further comprises: etching the channel region of the semiconductor layer so as to expose the amorphous silicon layer or the n+ amorphous silicon layer.

9. The method as claimed in claim 8, wherein the method further comprises forming source and drain electrodes, and etching the channel region of the semiconductor layer and forming the source and drain electrodes by a single patterning process.

10. The method as claimed in claim 9, wherein the step of etching the channel region of the semiconductor layer and forming the source and drain electrodes by the single patterning process comprises:
after forming the transparent electrode and removing the shading pattern, forming a metal film and forming a photoresist film on the metal film;
exposing the photoresist film formed over the substrate by a mask to a light, and developing it to form a part of fully reserved photoresist and a part of fully removed photoresist;
forming the source and drain electrodes by removing the metal film located at a position corresponding to the part of fully removed photoresist by an etching process, and etching the channel region of the semiconductor layer so as to expose the amorphous silicon layer; and
removing the photoresist film of the part of fully reserved photoresist.

11. The method as claimed in claim 10, wherein the part of fully reserved photoresist corresponds to a region where a conductive layer comprising the source and drain electrodes is to be formed, and the part of fully removed photoresist corresponds to other regions of the substrate except the conductive layer.

12. The method as claimed in claim 8, wherein after forming the shading pattern but before forming the transparent electrode, the method further comprises forming source and drain electrodes.

13. The method as claimed in claim 1, wherein the transparent electrode is a pixel electrode.

14. The method as claimed in claim 13, wherein the method further comprises forming a passivation layer and a common electrode.

15. A method for producing a display apparatus, comprising the method for producing the array substrate as claimed in claim 1.

16. The method as claimed in claim 15, further comprising forming a color filter substrate and assembling the array substrate and the color filter substrate.
